(19) United States
(12) Patent Application Publication
(10) Pub. No.: US 2026/0117372 A1
(43) Pub. Date: Apr. 30, 2026

(54) AVOIDING RECIRCULATION ZONES IN A VACUUM LINE OF A DEPOSITION TOOL

(71) Applicant: Lam Research Corporation, Fremont, CA (US)

(72) Inventors: Pankaj MISHRA PARASNATH, Bangalore (IN); Ashwin RAMESH, Chennai (IN); Lav KAUSHIK, Bangalore (IN); Peter Andrew LANGAN, Tigard, OR (US)

(21) Appl. No.: 19/118,962

(22) PCT Filed: Oct. 1, 2023
(86) PCT No.: PCT/US2023/075662

§ 371 Date: Apr. 7, 2025

Related U.S. Application Data
(60) Provisional application No. 63/380,669, filed on Oct. 24, 2022.

(51) Int. Cl. C23C 16/44

(52) U.S. Cl. CPC C23C 16/4408; C23C 16/4412

(57) ABSTRACT

One example provides a deposition tool. The deposition tool comprises a processing chamber and a vacuum system. The vacuum system comprises a vacuum line configured to carry a flow of exhaust from the processing chamber. The vacuum system further comprises a valve positioned within the vacuum line. The vacuum system further comprises a purge gas inlet disposed along the vacuum line.

### BACKGROUND

Semiconductor device fabrication processes may involve many steps of material deposition, patterning, and removal to form integrated circuits on substrates. Various methods can be used to selectively deposit materials onto a substrate. One example is chemical vapor deposition. Chemical vapor deposition processes involve flowing one or more precursor gases over a substrate within a processing chamber. Conditions in the processing chamber are controlled to cause the precursor gases to react and/or decompose on the substrate surface, thereby forming a film.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

One example provides a deposition tool. The deposition tool comprises a processing chamber and a vacuum system. The vacuum system comprises a vacuum line configured to carry a flow of exhaust from the processing chamber. The vacuum system further comprises a valve positioned within the vacuum line. The vacuum system further comprises a purge gas inlet disposed along the vacuum line.

In some such examples, the purge gas inlet alternatively or additionally is disposed upstream of the valve.

In some such examples, the purge gas inlet alternatively or additionally is disposed downstream of the valve.

In some such examples, the purge gas inlet alternatively or additionally is configured to direct a flow of purge gas toward the valve.

In some such examples, the purge gas inlet alternatively or additionally is incorporated in a purge component that forms a portion of the vacuum line.

In some such examples, the purge gas inlet alternatively or additionally comprises an opening formed in the purge component, the opening having an annular shape.

In some such examples, the purge gas inlet alternatively or additionally comprises a gap formed in the purge component, the gap having a width configured to provide a uniform purge gas flow at different radial locations of the opening.

In some such examples, the purge gas inlet alternatively or additionally comprises a plurality of openings formed in the purge component.

In some such examples, the purge component alternatively or additionally comprises a flange configured to connect to a valve component holding the valve.

In some such examples, the flange alternatively or additionally comprises a groove and a seal located in the groove.

In some such examples, the purge gas inlet alternatively or additionally is a first purge gas inlet, and the deposition tool alternatively or additionally comprises a second purge gas inlet disposed along the vacuum line on an opposite side of the valve as the first purge gas inlet.

In some such examples, the purge gas inlet alternatively or additionally comprises an opening in a side of the vacuum line.

In some such examples, the purge gas inlet alternatively or additionally is configured to direct a flow of purge gas in a diagonal direction relative to an axial direction of the vacuum line.

In some such examples, the deposition tool alternatively or additionally comprises a heater configured to heat the purge gas inlet.

Another example provides a purge component for a vacuum line of a deposition tool. The purge component comprises a body defining a portion of the vacuum line for a flow of exhaust from a processing chamber. The purge component further comprises a gas port configured to connect to a purge gas source. The purge component further comprises a purge gas inlet in fluid communication with the gas port. The purge gas inlet is configured to direct a flow of purge gas into the vacuum line. The purge component further comprises a connector configured to couple the body to another component of the vacuum line.

In some such examples, the purge gas inlet alternatively or additionally comprises an opening having an annular or partially annular shape.

In some such examples, the purge gas inlet alternatively or additionally comprises a gap having a width configured to provide a uniform purge gas flow at different radial locations of the opening.

In some such examples, the connector alternatively or additionally comprises a flange comprising a groove for a seal.

Another example provides a pipe spool component for a vacuum line of a deposition tool. The pipe spool component comprises a pipe segment defining a portion of the vacuum line for a flow of exhaust from a processing chamber. The pipe spool component further comprises a purge gas inlet comprising an opening in a side of the pipe segment. The pipe spool component further comprises a connector configured to couple the pipe segment to another component of the vacuum line.

In some such examples, the purge gas inlet alternatively or additionally is configured to direct a flow of purge gas in a diagonal direction relative to an axial direction of the flow of exhaust through the vacuum line.

### BRIEF DESCRIPTION OF THE DRAWINGS

FIG. 1 schematically shows an example deposition tool.

FIG. 2 schematically shows an example vacuum line comprising a purge component.

FIG. 3 schematically shows a bottom view of the purge component of FIG. 2 taken along line 3-3 of FIG. 2.

FIG. 4 schematically shows a bottom view of another example purge component.

FIG. 5 schematically shows an example vacuum line comprising with a purge component with an angled gas port.

FIG. 6 schematically shows an example vacuum line comprising a purge gas inlet upstream of a valve.

FIG. 7 schematically shows another example vacuum line comprising a purge gas inlet downstream of a valve.

### DETAILED DESCRIPTION

The term “annular shape” may generally represent a substantially ring-like shape defining an opening.

The term “body” may generally represent a physical mass of a component of a vacuum line.

The term “chemical vapor deposition” (CVD) may generally represent a process in which a solid phase film is formed on a substrate by directing a flow of one or more precursor gases over the substrate surface under conditions configured to cause the chemical conversion of the precursor gases to the film.

The term “connector” may generally represent a physical structure configured to fasten a component of a vacuum line to an adjoining component of the vacuum line.

The terms “deposition” and variants thereof may generally represent a process in which a film is formed on a substrate in a processing chamber. An example deposition process is CVD.

The term “deposition tool” may generally represent a machine comprising a processing chamber and other hardware configured to enable a deposition process to be carried out in the processing chamber.

The term “exhaust” may generally represent gases that are evacuated from a processing chamber of a deposition tool. Examples of gases in processing chamber exhaust include unreacted precursors, reaction byproducts, and inert gases.

The term “flange” may generally represent an outwardly projecting rim of a component of a vacuum line to couple the component to another component of the vacuum line.

The term “gap” may generally represent a volume of space formed in a purge component that acts as a plenum for purge gas flow in the purge component.

The term “gas port” may generally represent a physical structure on a purge component configured to connect to a purge gas source.

The term “opening” may generally represent an area along a vacuum line in which a purge gas is introduced into the vacuum line using a purge gas inlet.

The term “pipe segment” may generally represent a portion of a pipe spool component that defines a passage for flow of exhaust from a processing chamber.

The term “precursor gas” may generally represent a material introduced to a processing chamber to form a film on a substrate disposed within the processing chamber. An example precursor gas is tetraethyl orthosilicate (TEOS).

The term “processing chamber” may generally represent an enclosure in which chemical and/or physical processes are performed on substrates. Example chemical processes include deposition processes, such as chemical vapor deposition (CVD).

The term “purge component” may generally represent a physical structure that forms a portion of a vacuum system. A purge component comprises a purge gas inlet and a gas port.

The term “purge gas” may generally represent a gas used to remove other gases from at least a portion of a processing chamber and/or at least a portion of a vacuum line. Examples of purge gases for use in a vacuum line include nitrogen, argon, and clean dry air.

The term “purge gas inlet” may generally represent a structure configured to direct a flow of purge gas into an interior of a vacuum line.

The term “seal” may generally represent a physical structure that helps to separate one fluid environment from another fluid environment. Example seals include O-rings and centering rings.

The term “pipe spool component” may generally represent a physical structure that forms a portion of a vacuum line of a deposition tool. A pipe spool component can comprise a purge gas inlet.

The term “substrate” may generally represent any object on which a film can be deposited.

The term “vacuum line” may generally represent a physical pathway comprising pipes, valves and other components for removing exhaust from a processing chamber of a deposition tool.

The term “vacuum system” may generally represent a vacuum line, one or more pumps, and other hardware configured to evacuate exhaust from a processing chamber of a deposition tool.

The term “valve” may generally represent a physical structure disposed within a vacuum line and used to maintain a process pressure in a processing chamber. Example valves include a pendulum valve and a combination valve.

The term “valve component” may generally represent a physical structure that forms a portion of a vacuum line and holds a valve.

As mentioned above, the fabrication of integrated circuits on substrates involves many individual steps of material addition, patterning, modification, and removal. Chemical vapor deposition may be used to deposit films of a variety of compositions on a substrate surface. Chemical vapor deposition involves exposing a substrate to one or more reactive precursor gases under conditions that cause the precursor gas(es) to react and/or decompose on the substrate.

Chemical vapor deposition is generally performed in a processing chamber under a controlled gaseous environment. During a chemical vapor deposition process, a vacuum system draws exhaust gases from the processing chamber and through a vacuum line for evacuation. A vacuum system also may comprise a controllable valve that can be adjusted during operation to maintain a process pressure in the processing chamber.

However, under some conditions, recirculation zones may form in the flow of exhaust in the vacuum line near the valve. Such recirculation zones may result in unreacted film precursor accumulating in the recirculating zones. This can result in the formation and accumulation of powder residue in the vacuum line over time as the unreacted precursor converts to grains of the material being deposited. As a more specific example, unreacted TEOS in a vacuum line may form silicon oxide powder. Such powder accumulation may cause negative leaks that may interfere with reaching low pressure process conditions in the processing chamber. As a result, substrate processing pressure conditions may be difficult to reach.

To avoid such problems, the vacuum line may be periodically disassembled and cleaned to remove the powder accumulation. However, such disassembly and cleaning results in substantial tool down time and associated expense.

One possible solution to prevent such powder formation is to add heaters along portions of the vacuum line to help avoid condensation of the precursor gas that can result in powder accumulation. However, heating portions of the vacuum line may not prevent powder formation sufficiently.

Accordingly, examples are disclosed that relate to introducing a purge gas into a vacuum line of a deposition tool to reduce recirculation zones in the vacuum line. Briefly, the disclosed examples utilize a purge gas inlet disposed along the vacuum line to reduce recirculation zones in the vacuum line in a vicinity of a valve. In various examples, purge gas inlet(s) can be disposed upstream and/or downstream of the valve. Each purge gas inlet directs a flow of purge gas into the vacuum line in a direction that helps to avoid forming recirculating exhaust flow. In such a manner, the purge gas inlet may help to reduce recirculation zones in the vicinity of the valve during a deposition process. Reducing the recirculation zones helps to reduce residence times of unreacted precursor gas in the vacuum line. This may help to avoid powder accumulation in the vacuum line. While described herein in the context of a TEOS precursor gas, the purge gas inlet(s) may be used to reduce recirculation zones in a vacuum line in a deposition for any suitable deposition process using any suitable precursor.

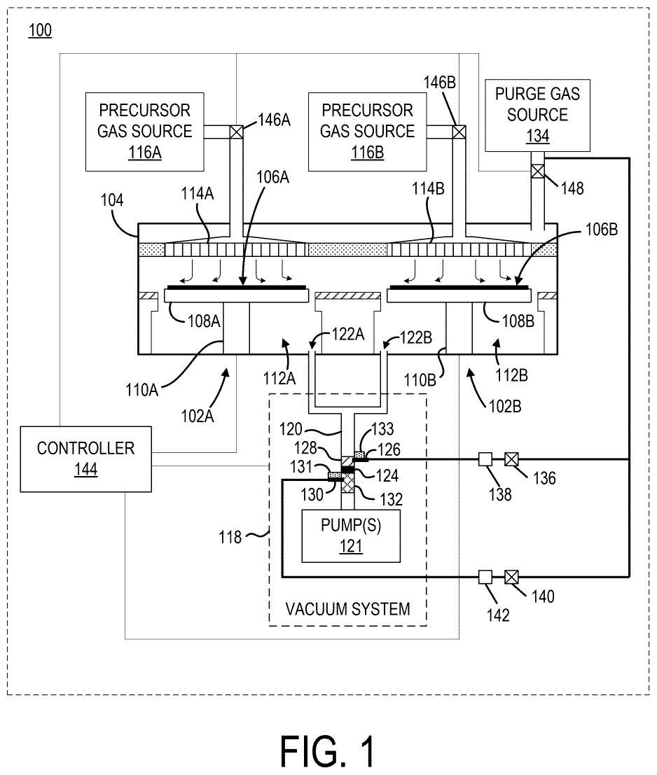

Prior to discussing these examples in detail, FIG. 1 shows a schematic view of an example deposition tool 100. In some examples, deposition tool 100 may be configured for depositing large area films at relatively high deposition rates. In other examples, deposition tool 100 may be configured for carbon chemical vapor deposition. Deposition tool 100 comprises a first processing station 102A and a second processing station 102B positioned within a processing chamber 104. First processing station 102A and second processing station 102B are configured to expose substrates 106A, 106B to one or more precursor gases during a deposition process. Deposition tool 100 further may comprise additional stations not shown in FIG. 1. In some examples, deposition tool 100 comprises four stations.

First processing station 102A comprises a first substrate holder 108A and a first substrate holder support 110A positioned within a first well 112A of processing chamber 104. First processing station 102A further comprises a first process gas outlet 114A in fluid connection with a first precursor gas source 116A. First precursor gas source 116A is configured to provide one or more precursor gases to first process gas outlet 114A. First substrate holder 108A supports a first substrate 106A during a deposition process. First substrate holder support 110A may be configured to raise and lower first substrate holder 108A, for example, to adjust a gap between first substrate holder 108A and first process gas outlet 114A.

Similarly, second processing station 102B comprises a second substrate holder 108B and a second substrate holder support 110B positioned within a second well 112B. Second processing station 102B further comprises a second process gas outlet 114B in fluid connection with a second precursor gas source 116B. Second precursor gas source 116B is configured to provide one or more precursor gases to second process gas outlet 114B. Second substrate holder 108B supports second substrate 106B during the deposition process at second processing station 102B. Second substrate holder support 110B may be configured to raise and lower second substrate holder 108B.

Processing tool 100 further comprise a vacuum system 118 to evacuate processing chamber 104. Vacuum system 118 comprises a vacuum line 120 configured to carry a flow of exhaust from processing chamber 104. Vacuum system 118 also comprises one or more pumps 121. The exhaust may comprise unreacted precursor, deposition byproducts, and/or inert gases used in the deposition process. In the depicted example, exhaust from first processing station 102A enters vacuum system 118 through a first exhaust port 122A. Similarly, exhaust from second processing station 102B enters vacuum system 118 through a second exhaust port 122B. Vacuum lines from first exhaust port 122A and second exhaust port 122B then combine into vacuum line 120. Vacuum system 118 further comprises a valve component 124. Valve component 124 holds a valve configured to maintain a process pressure in processing chamber 104 during the deposition process. Examples of the valve include a pendulum valve or a combination valve.

Vacuum system 118 further comprises a first purge gas inlet 126 disposed along vacuum line 120. First purge gas inlet 126 is configured to direct a flow of purge gas into vacuum line 120. In this example, first purge gas inlet 126 is configured to direct the flow of purge gas towards the valve of valve component 124. Such a configuration may help to reduce recirculation zones in the flow of exhaust near valve component 124. This may help to reduce or prevent powder accumulation in a vicinity of the valve. In the depicted example, first purge gas inlet 126 is incorporated in a purge component 128 upstream of valve component 124. Purge component 128 forms a portion of vacuum line 120. While purge component 128 is shown as a separate component of vacuum line 120, in other examples purge component 128 can be incorporated into another component of vacuum line 120.

Vacuum system 118 further comprises a second purge gas inlet 130. Second purge gas inlet 130 is disposed downstream of valve component 124. Similar to first purge gas inlet 126, second purge gas inlet 130 is configured to direct a flow of purge gas into vacuum line 120. In the depicted example, second purge gas inlet 130 is incorporated in a pipe spool component 132. Pipe spool component 132 forms a portion of vacuum line 120. In other examples, one of first purge gas inlet 126 or second purge gas inlet 130 may be omitted. Further, in yet other examples, additional purge gas inlets may be included in a vacuum line of a deposition tool.

Deposition tool 100 further comprises a purge gas source 134 comprising a purge gas that can be directed into processing chamber 104. As shown, the purge gas is directed from purge gas source 134 to first purge gas inlet 126 through a first purge valve 136 and a first orifice 138. First orifice 138 controls a purge gas flow rate through first purge gas inlet 126. Thus, a size of first orifice 138 may be selected based on a desired flow rate of the flow of purge gas to first purge gas inlet 126. In the depicted configuration, first orifice 138 can be exchanged without breaking a vacuum condition of processing chamber 104. This may allow for the adjustment of purge gas flow rates without incurring tool downtime. In other examples, a flow mass controller may be used instead of first orifice 138.

Similarly, a flow of purge gas also is directed to second purge gas inlet 130 through a second purge valve 140 and a second orifice 142. Second orifice 142 controls a purge gas flow rate through second purge gas inlet 130. Thus, a size of second orifice 142 may be selected based on a desired flow rate of the flow of purge gas to second purge gas inlet 130. In the depicted configuration, second orifice 142 can be exchanged without breaking a vacuum condition of processing chamber 104. Further, in other examples, a mass flow controller may be used to control gas flow rates through second purge gas inlet 130.

In the example of FIG. 1, flows of purge gas to first purge gas inlet 126 and second purge gas inlet 130 can be controlled separately. For example, purge flow timings may be controlled separately for first purge gas inlet 126 and second purge gas inlet 130 by controlling first purge value 136 and second purge valve 140. In the depicted example, first purge gas inlet 126 and second purge gas inlet 130 receive purge gas from purge gas source 134. In other examples, first purge gas inlet 126 and second purge gas inlet 130 each can receive the purge gas from separate purge gas sources. In some examples, the purge gas may be heated before reaching first purge gas inlet 126 and/or second purge gas inlet 130. Thus, each of first purge gas inlet 126 and/or second purge gas inlet 130 optionally can comprise a heater configured to heat the purge gas, as indicated at 131 and 133. Heating the purge gas may further help to avoid condensation of unreacted precursor in vacuum line 120.

Deposition tool 100 further comprises a controller 144 configured to control deposition tool 100 to perform process cycles. For example, controller 144 is connected to process valves 146A, 146B, first and second purge valves 136, 140, and a chamber purge valve 148. Controller 144 is also connected to vacuum system 118. In some examples, controller 144 selectively directs the purge gas to first purge gas inlet 126 and/or second purge gas inlet 130 when the exhaust is flowing through vacuum line 120. As a more specific example, nitrogen gas may be directed to first purge gas inlet 126 and second purge gas inlet 130 during a silicon oxide deposition process using TEOS as a precursor. Controller 144 further may control process valves 146A, 146B, chamber purge valve 148, and vacuum system 118 to control pressure and gas composition inside processing chamber 104.

Controller 144 also may control substrate holder supports 110A, 110B to raise and lower substrates. Controller 144 additionally may control other components not shown in FIG. 1, such as substrate holder heaters, gas line heaters, substrate transfer robots, load locks, and/or any other suitable components.

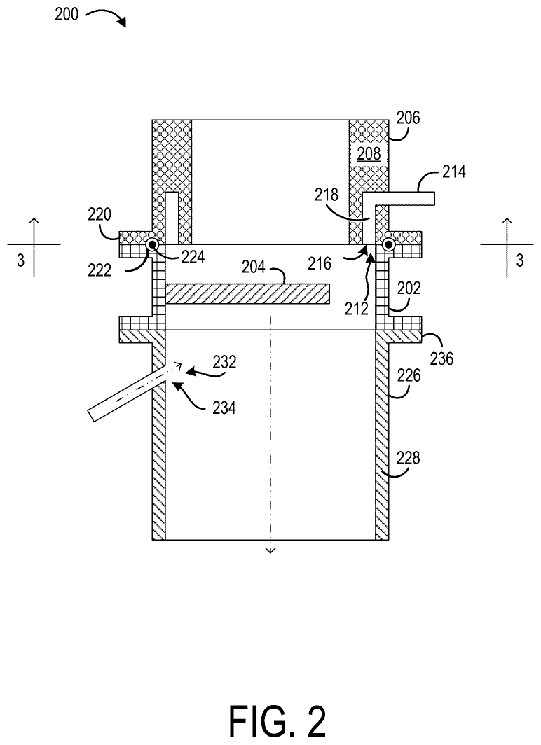

FIG. 2 schematically shows a schematic depiction of a portion of an example vacuum line 200 of a vacuum system. Vacuum line 200 is an example of vacuum line 120. Vacuum line 200 comprises a valve component 202 holding a valve 204. In the depicted example, valve 204 comprises a pendulum valve. In other examples, valve 204 can comprise a combination valve or other suitable valve. Pipe spool components above and below the depicted portion of vacuum line 200 are omitted for clarity.

Vacuum system 200 further comprises a purge component 206. Purge component 206 comprises a body 208. Body 208 defines a first portion of vacuum line 200. A first purge gas inlet 212 is in fluid communication with a gas port 214. Gas port 214 is configured to connect to a purge gas source. First purge gas inlet 212 is configured to direct a flow of purge gas into vacuum line 200. As shown, gas port 214 comprises an orientation that is approximately orthogonal relative to first purge gas inlet 212. In other examples, a gas port may have a different orientation than that shown.

First purge gas inlet 212 comprises an opening 216. First purge gas inlet 212 further comprises a gap 218 between gas port 214 and opening 216. Gap 218 is configured to act as a plenum for a flow of purge gas from gas port 214. As such, gap 218 has a width configured to provide a suitably uniform purge gas flow through opening 216 at different radial locations of opening 216. The term “suitably uniform purge gas flow” is a flow that reduces the formation of recirculation zones where powder can accumulate due to unreacted precursor. More specifically, the width of the gap is configured to allow the purge gas to flow circumferentially through gap 218 and then through opening 216 towards valve 204. With such a configuration, gap 218 may help to reduce recirculation zones in a vicinity of valve 204. In this manner, gap 218 may help to reduce a powder accumulation in the vicinity of valve 204. The width of gap 218 and/or the flow volume of purge gas through first purge gas inlet 212 may be selected based on a desired velocity contour that results in reduced recirculation zones and species mass fraction of the precursor gas in the locations where recirculation zones otherwise may form.

Purge component 206 further comprises a connector. The connector is configured to couple body 208 to valve component 202. As shown, the connector comprises a flange 220 comprising a groove 222 for a seal 224. Seal 224 can comprise an O-ring, a centering ring, or any other suitable seal. In other examples, any other suitable connector may be used. Purge component 206 further comprises a second connector (not shown) on an opposite end compared to flange 220 to couple body 208 to another component of vacuum line 200. While purge component 206 is shown adjacent to valve component 202, in other examples, an intermediate component may be located between purge component 206 and valve component 202. In further examples, a purge component can be alternatively or additionally positioned downstream of valve 204.

Vacuum system 200 further comprises a pipe spool component 226 positioned downstream of valve 204. Pipe spool component 226 comprises a pipe segment 228. Pipe segment 228 defines another portion of vacuum line 200. Pipe spool component 226 further comprises a second purge gas inlet 232 comprising an opening 234 in a side of pipe segment 228. In this example, second purge gas inlet 232 is configured to direct a flow of the purge gas in a diagonal direction relative to an axial direction of a flow of exhaust through vacuum line 200. As depicted, the diagonal direction is towards valve 204. This may help to reduce recirculation zones in the vicinity of valve 204. Thus, this may help to reduce or avoid powder formation and accumulation. An angle of the diagonal direction may be selected based at least on a desired velocity contour in the vicinity of valve 204. In other examples, second purge gas inlet 232 may direct the flow of purge gas in any other suitable direction than that shown. Pipe spool component 226 further comprises a connector 236. Connector 236 comprises a flange, and is configured to couple pipe segment 228 to valve component 202. In other examples, other suitable connectors may be used. Pipe spool component 226 further comprises a second connector (not shown) located on an opposite end compared to connector 236 to couple pipe segment 228 to another component of vacuum line 200.

In the depicted example, pipe spool component 226 comprises a single purge gas inlet. In other examples, a pipe spool component may comprise two or more purge gas inlets. Each purge gas inlet may direct the flow of the purge gas in any suitable direction to help prevent formation of recirculation zones.

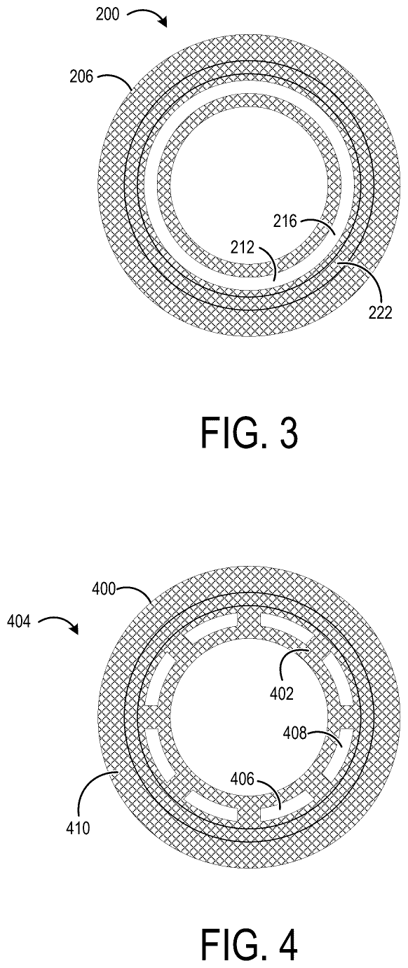

FIG. 3 schematically shows a bottom view of purge component 206 taken along line 3-3 of FIG. 2. As previously mentioned, first purge gas inlet 212 comprises an opening 216. As shown, opening 216 has an annular shape. The annular shape may help to reduce recirculation zones around a circumference of vacuum line 200. In other examples, opening 216 may have a partially annular shape, or other suitable shape.

FIG. 4 schematically shows a bottom view of another example purge component 400 comprising a plurality of openings. Purge component 400 is an example of purge component 128. Purge component 400 comprises a body 402 that defines a portion of a vacuum line 404. Purge component 400 further comprises a purge gas inlet 406 configured to direct a flow of purge gas into vacuum line 404. As shown, purge gas inlet 406 comprises a plurality of openings 408 formed in purge component 400. In other examples, purge gas inlet 406 may comprise a different arrangement of a plurality of openings. Purge component 400 further comprises a connector 410 in the form of a flange.

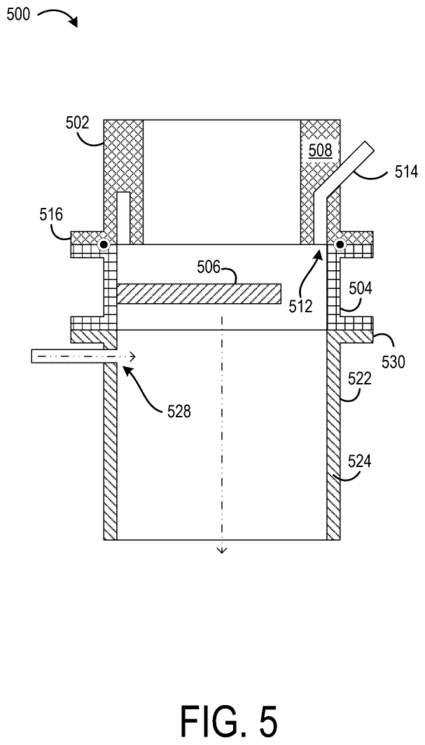

FIG. 5 schematically depicts a portion of another example vacuum line 500 with a purge component 502. Purge component 502 comprises a diagonal gas port. Vacuum line 500 is an example of vacuum line 120. Vacuum line 500 comprises a valve component 504 holding a valve 506. Purge component 502 is positioned upstream of valve 506. Purge component 502 comprises a body 508 that defines a portion of vacuum line 500. A first purge gas inlet 512 is in fluid communication with a gas port 514. Gas port 514 is configured to connect to a purge gas source. First purge gas inlet 512 is configured to direct a flow of purge gas into vacuum line 500. As shown, gas port 514 comprises a diagonal orientation relative to first purge gas inlet 512. Such a configuration may help to reduce a loss of velocity in the flow of purge gas compared to a gas port with an orthogonal orientation. Purge component 502 further comprises a connector 516 to connect purge component 502 to valve component 504 or other suitable component.

Vacuum system 500 further comprises a pipe spool component 522 positioned downstream of valve 506. A pipe segment 524 of pipe spool component 522 defines another portion of vacuum line 500. Pipe spool component 522 comprises a second purge gas inlet 528. Second purge gas inlet 528 comprises an opening in a side of pipe segment 524. As shown, second purge gas inlet 528 is configured to direct a flow of purge gas in an approximately orthogonal direction relative to an axial direction of a flow of exhaust through vacuum line 500. In other examples, a pipe spool component may comprise two or more purge gas inlets. Pipe spool component 522 further comprises a connector 530. Connector 530 is configured to couple pipe segment 524 to valve component 504 to connect pipe spool component 522 to valve component 504 or other suitable component.

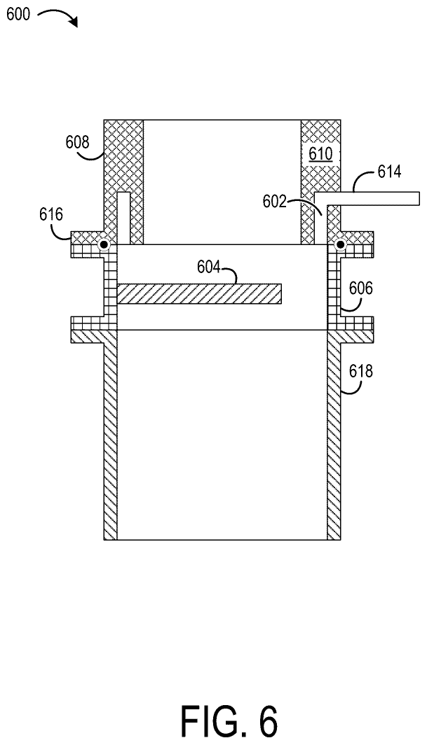

In the examples above, a first purge gas inlet is disposed upstream of a valve and a second purge gas inlet is disposed downstream of the valve. In other examples, a vacuum system may use a single purge gas inlet. FIG. 6 schematically shows a portion of an example vacuum line 600 with a purge gas inlet 602 disposed upstream of a valve 604. Vacuum line 600 can be used in deposition tool 100, for example. Vacuum line 600 comprises a valve component 606 holding valve 604. A purge component 608 is positioned upstream of valve 604. Purge component 608 comprises a body 610 that defines a portion of vacuum line 600. Purge component 608 further comprises a purge gas inlet 602 in fluid communication with a gas port 614. In various examples, purge gas inlet 602 and gas port 614 can be configured in any suitable manner discussed herein. Purge component 608 further comprises a connector 616. Connector 616 is configured to couple body 610 to valve component 606 or other suitable component. A pipe spool component 618 is positioned downstream of valve 604. In this example, pipe spool component 618 omits a purge gas inlet.

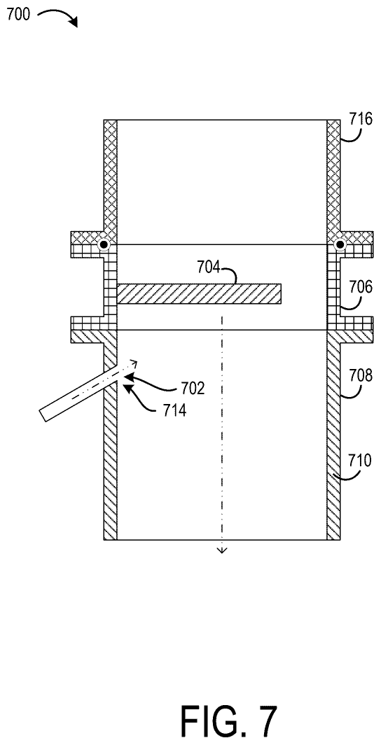

FIG. 7 schematically shows a portion of another example vacuum line 700 with a purge gas inlet 702 disposed downstream of a valve 704. Vacuum line 700 can be used in deposition tool 100, for example. Vacuum line 700 comprises a valve component 706 holding valve 704. A first pipe spool component 708 is positioned downstream of valve 704. First pipe spool component 708 comprises a pipe segment 710 that defines a portion of vacuum line 700. First pipe spool component 708 comprises purge gas inlet 702 comprising an opening 714 in a side of pipe segment 710. In various examples, purge gas inlet 702 can be configured in any suitable manner discussed herein. Vacuum system 700 further comprises a second pipe spool component 716 positioned upstream of valve 704. In the depicted example, second pipe spool component 716 omits a purge gas inlet. In other examples, second pipe spool component 716 may comprise an additional purge gas inlet. Similar to purge gas inlet 702, the additional purge gas inlet may comprise an opening in a side of second pipe spool component 716.

A vacuum system comprising one or more purge gas inlets as disclosed herein may help to reduce recirculation zones in a flow of exhaust in a vacuum line near a valve. Thus, the one or more purge gas inlets may help to reduce a powder accumulation from a precursor gas in a vicinity of the valve during a deposition process. this may help to reduce deposition tool downtime for cleaning the powder accumulation.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A deposition tool comprising:
a processing chamber; and
a vacuum system comprising
a vacuum line configured to carry a flow of exhaust from the processing chamber,
a valve positioned within the vacuum line, and
a purge gas inlet disposed along the vacuum line.

2. The deposition tool of claim 1, wherein the purge gas inlet is disposed upstream of the valve.

3. The deposition tool of claim 1, wherein the purge gas inlet is disposed downstream of the valve.

4. The deposition tool of claim 1, wherein the purge gas inlet is configured to direct a flow of purge gas toward the valve.

5. The deposition tool of claim 1, wherein the purge gas inlet is incorporated in a purge component that forms a portion of the vacuum line.

6. The deposition tool of claim 5, wherein the purge gas inlet comprises an opening formed in the purge component, the opening having an annular shape.

7. The deposition tool of claim 6, wherein the purge gas inlet comprises a gap formed in the purge component, the gap having a width configured to provide a uniform purge gas flow at different radial locations of the opening.

8. The deposition tool of claim 5, wherein the purge gas inlet comprises a plurality of openings formed in the purge component.

9. The deposition tool of claim 5, wherein the purge component comprises a flange configured to connect to a valve component holding the valve.

10. The deposition tool of claim 9, wherein the flange comprises a groove and a seal located in the groove.

11. The deposition tool of claim 1, wherein the purge gas inlet is a first purge gas inlet, and further comprising a second purge gas inlet disposed along the vacuum line on an opposite side of the valve as the first purge gas inlet.

12. The deposition tool of claim 1, wherein the purge gas inlet comprises an opening in a side of the vacuum line.

13. The deposition tool of claim 1, wherein the purge gas inlet is configured to direct a flow of purge gas in a diagonal direction relative to an axial direction of the vacuum line.

14. The deposition tool of claim 1, further comprising a heater configured to heat the purge gas inlet.

15. A purge component for a vacuum line of a deposition tool, the purge component comprising:
a body defining a portion of the vacuum line for a flow of exhaust from a processing chamber;
a gas port configured to connect to a purge gas source;
a purge gas inlet in fluid communication with the gas port, the purge gas inlet configured to direct a flow of purge gas into the vacuum line; and
a connector configured to couple the body to another component of the vacuum line.

16. The purge component of claim 15, wherein the purge gas inlet comprises an opening having an annular or partially annular shape.

17. The purge component of claim 16, wherein the purge gas inlet further comprises a gap having a width configured to provide a uniform purge gas flow through different radial locations of the opening.

18. The purge component of claim 15, wherein the connector comprises a flange comprising a groove for a seal.

19. A pipe spool component for a vacuum line of a deposition tool, the pipe spool component comprising:
a pipe segment defining a portion of the vacuum line for a flow of exhaust from a processing chamber;
a purge gas inlet comprising an opening in a side of the pipe segment; and
a connector configured to couple the pipe segment to another component of the vacuum line.

20. The pipe spool component of claim 19, wherein the purge gas inlet is configured to direct a flow of purge gas in a diagonal direction relative to an axial direction of the flow of exhaust through the vacuum line.
